(19) United States
(12) Patent Application Publication
(10) Pub. No.: US 2006/0269657 A1
(43) Pub. Date: Nov. 30, 2006

(54) Organic luminescence ink and an organic electroluminescence element

(76) Inventors: Takahisa Shimizu, Tokyo (JP); Koji Takeshita, Tokyo (JP); Hironori Kawakami, Tokyo (JP)

Correspondence Address: SQUIRE, SANDERS & DEMPSEY L.L.P., 1 MARITIME PLAZA, SUITE 300, SAN FRANCISCO, CA, 94111, US

(21) Appl. No.: 11/436,505

(22) Filed: May 17, 2006

(30) Foreign Application Priority Data
May 27, 2005 (JP) 2005-155020

(51) Int. Cl. B05D 5/12; C09K 11/06

(52) U.S. Cl. 427/66; 252/301.16

(57) ABSTRACT

An organic luminescence ink is disclosed. The ink includes a solvent and organic luminescent material dissolved in the solvent. The solvent comprises solvent A having a boiling point more than 70 degrees Celsius and under 180 degrees Celsius and solvent B having a boiling point more than 180 degrees Celsius and less than or equal to 270 degrees Celsius. An amount of solvent B in sum of an amount of solvent A and solvent B is more then 5% by weight and less than or equal to 30% by weight.

### CROSS REFERENCE

This application claims priority to Japanese application number 2005-155020, filed on May 27, 2005, which is incorporated by reference.

### BACKGROUND OF THE INVENTION

1. Field of the Invention

The present invention is related to an organic luminescence ink which can be used for the formation of an organic luminous layer of an organic electroluminescence device. The present invention is also related to a method of producing organic electroluminescence device with this ink.

2. Description of the Related Art

Electric current is applied to an organic luminous layer of electroconductivity. Then a hole couples to poured electron again. In this recombination, organic luminescent material comprising the organic luminous layer emits light.

In the case of application of electric current to the organic luminous layer, it is necessary to take the light outside. Therefore transparent electrode and opposed electrode are installed on either side of the organic luminous layer.

This device is the layer stack of a transparent electrode, an organic luminous layer and an opposed electrode, laminated by this sequence on a transparent substrate. Usually, a transparent electrode is used as anode, and an opposed electrode is utilized as cathode.

It is often that the following constitution of organic electroluminescence device is adopted to improve luminous efficiency. A hole transport layer and a hole injection layer is provided between the anode and the organic luminous layer. An electronic transport layer and an electron injection layer are provided between the organic luminous layer and the cathode. The organic luminous layer and the hole transport layer, a hole injection layer, an electronic transport layer and an electron injection layer are referred to as an organic luminescence media layer.

Examples of organic luminescence media layer include the following: copper phthalocyanine is used for hole injection layer. N,N′-di(1-naphthyl)-N,N′-diphenyl-1,1′-biphenyl-4,4′-diamine is used for a hole transport layer. Tris (8-quinolinol) aluminium is used for organic luminous layer.

All of luminescence medium material including the organic luminescent material which is material comprising these organic luminescence media layers are chemical compounds of low molecular weight. Thickness of each layer of organic luminescence media layer is from 1 nm to about 100 nm. Each layer of organic luminescence media layer is laminated by vacuum evaporation such as resistance heating method. Because of this, for manufacture of an organic thin film electroluminescence device using low molecular material, the vacuum evaporation system having a plural evaporation kettle is needed. Therefore, productivity is low and the manufacture cost is high.

In addition, high minute patterning of the luminous layer is necessary to make a matrix display unit. However, a minute mask is needed to form pattern-shaped thin film by evaporation method such as resistance heating evaporation method. And patterning accuracy is worsened when the substrate on which thin film is formed is upsized.

On the other hand, there is a macromolecule electroluminescence device with the use of a polymeric material as luminescent material included by an organic luminous layer.

The following material can be used for an organic luminous layer: material which luminescence coloring agent of low molecular weight which dissolves in macromolecule and macromolecule luminescent material.

By way of example only, the following material can be used: material which fluorescent dye of low molecular weight which dissolves in macromolecule such as polystyrene, polymethyl methacrylate and polyvinylcarbazole, macromolecule fluorescent or phosphorus luminous material such as a polyphenylene vinylene derivative (PPV) and a poly alkylfluorene derivative (PAF).

Ink is made by means of dissolving or dispersing these polymeric materials in stable in solvent. Film production is made by means of application method and a printing method with the use of this ink. Therefore, film production under air pressure is possible. The facility cost is inexpensive. Organic electroluminescence device by this method can be superior to organic electroluminescence device layered by evaporation with the use of the above-mentioned low molecular weight material.

As methods of coating, spin coat method, dipping, bar coat method and slit coat (die coat) method are generally exemplified. However, when polymeric material is applied by these methods, it is difficult to form thin film of uniform thickness in large area. It is necessary to form thin film of uniform thickness in large domain so that organic electroluminescence device emits light uniformly. In addition, due to coating of ink to a whole area of a substrate, it is necessary to remove ink on electrode takeout parts. In addition, by these application methods, only one color layer can be formed in one layer. Therefore, in order to make three primary colors display, it is necessary to use a color filter. Therefore, the cost of such member is high.

The following coating is difficult by wet coating method: the formation of high minute pattern; and pattern formation of three colors of RGB which is separated.

On the other hand, printing method is suitable for the formation of separated pattern and the formation of high minute pattern. Therefore, thin film formation by a printing method is more effective.

As a printing method, various printing methods such as an intaglio printing, relief printing, lithography and screen printing are exemplified. As for the organic electroluminescence device, it is often that a glass substrate is used as a substrate supporting electrodes. Gravure printing uses hard metal printing plate. Therefore, in gravure printing, there is danger that a substrate is damaged. In addition, the cost is high when printing plate is a metallograph and exchange of printing plate is not easy.

In addition, the offset printing that is lithography is not suitable for the formation of an organic luminescence media layer due to viscosity of the ink. The offset printing uses ink of high viscosity.

Screen printing is not suitable for the formation of an organic luminescence media layer due to viscosity of the,ink. Even more particularly, screen printing is the printing process which accuracy is essentially low. Therefore, it is difficult to form thin film of less than or equal to 0.1 μm that are the film thickness which is necessary for an organic luminous layer.

On the other hand, relief printing method fits viscosity range of organic luminescence ink. Depending on choice of printing plate material, a substrate is not damaged. Therefore, relief printing method is the printing method that is suitable for organic electroluminescence. Organic electroluminescence device is made in high speed by relief printing method. In addition, ink including very expensive organic luminescent material is printed only onto a necessary part of a substrate. Therefore, material can be used without waste.

Relief printing plate is used as printing plate. Ink is held in convex parts of the printing plate. Ink is put from the convex part to a substrate. Conventionally, a metal such as lead has been used as material of the printing plate. In late years a cheap, light photosensitive resin has been used. In addition, as an example of relief printing method, the flexography that material of printing plate is rubber or a photosensitive resin is exemplified. Relief printing plate made of a photosensitive resin is referred to as plastic plate in the present specification.

In the formation of organic electroluminescence layer by a printing method, as for the ink, it should not be dried. Therefore it is suggested that the following ink is used: ink for organic electroluminescence including at least one kind of solvent with vapor pressure less than 500 Pa. (Japanese Patent Laid-Open No. 2001-155861 Official Gazette)

Even more particularly, from the viewpoint of membranous surface characteristics, there is description that vapor pressure of less than or equal to 250 Pa is desirable. In addition, it is desirable that the solvent with vapor pressure at a temperature of printing is lower than 500 Pa is more than 50wt % of the ink when mixed in solution of solvents with more than two kinds.

However, the following phenomena were found by the inventor of this invention. When percentage of the solvent having a high boiling point included in the ink is high, the following phenomena occur. (e.g., ink including the single solvent that boiling point is high is used.) An ink pattern for the formation of an organic luminous layer is formed on a substrate. As for this ink pattern, it is dried by heating at reduced pressure. Then the solvent having the high boiling point is removed but not completely. In other words, some of the solvent with the high boiling point remains in an organic luminous layer. For this reason, emission lifetime of organic electroluminescence device shortens.

On the other hand, when percentage of the solvent with the high boiling point included in ink is small, the following phenomena occurs.

Ink dries during printing. Ink on printing plate is not transferred to a substrate well. Solvent suddenly decreases in a drying step of ink on a substrate. Therefore, thickness of organic electroluminescence layer becomes nonuniform. Unevenness of a color occurs in a pixel for device.

Thus, in the present invention, solvent included by ink to form an organic luminous layer is optimized. As thus described, a problem of residual solvent after having formed the device is solved: Organic electroluminescence device having a long life is obtained. In addition, an organic luminous layer is formed uniformly. Surface state is fixed. As thus described, when device is formed, organic electroluminescence device without color unevenness is obtained.

### SUMMARY OF THE INVENTION

An organic luminescence ink is disclosed. The ink includes solvent and organic luminescent material dissolved in the solvent, said solvent including solvent A having a boiling point more than 70 degrees Celsius and under 180 degrees Celsius and solvent B having a boiling point more than 180 degrees Celsius and less than or equal to 270 degrees Celsius, wherein an amount of solvent B in sum of an amount of solvent A and solvent B is more than 5 % by weight and less than or equal to 30 % by weight.

Residual solvent in an organic luminous layer can be controlled by optimizing solvent included in an organic luminous layer. Therefore, organic electroluminescence device of long life is able to be obtained. In addition, sudden drying of the ink pattern can be prevented. Therefore, an organic luminous layer of uniform thickness can be obtained. Organic electroluminescence device without unevenness-colored in a pixel can also be obtained.

### BRIEF DESCRIPTION OF DRAWINGS

FIG. 1A is a cross-section of an example of the organic electroluminescence device having a organic luminous layer formed with an organic luminescence ink of the present invention.

FIG. 1B is a cross-section of an example of the organic electroluminescence device having a organic luminous layer formed with an organic luminescence ink of the present invention.

FIG. 1C is a cross-section of an example of the organic electroluminescence device having a organic luminous layer formed with an organic luminescence ink of the present invention.

FIG. 2 is a figure which shows an example of relief printing device used in the present invention.

### DESCRIPTION OF THE PREFERRED EMBODIMENT

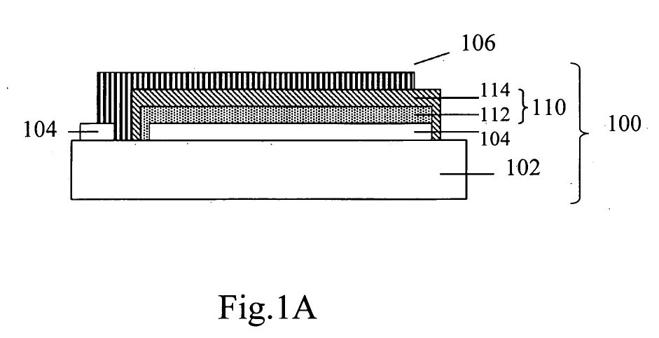

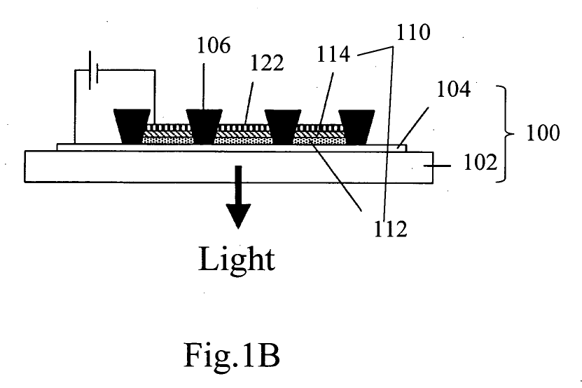

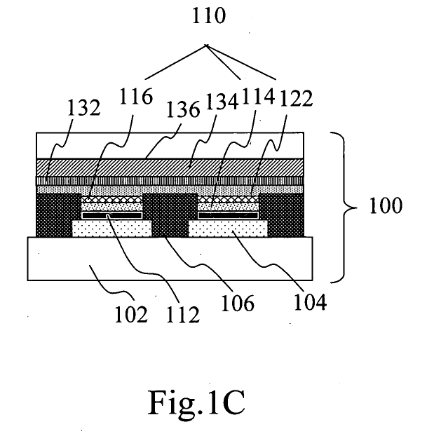

An example of organic luminescence ink and an organic electroluminescence element of the present invention are explained as follows. It is explained based on FIG. 1.

### Organic Electroluminescence Device

Organic electroluminescence device 100 of the present invention can include substrate 102, first electrode 104, organic luminous layer 114 and second electrode 122 at least as illustrated by FIGS. 1A, 1B and 1C. The sequence can be as is listed. In addition, an organic luminous layer is formed by organic luminescence ink of the present invention.

A substrate to form organic luminous layer 114 is explained below.

Transparent electrode corresponding to first electrode 104 can be formed on substrate 102. Thereupon, hole transport layer 112 including hole transport material is formed.

### Substrate

Substrate 102 which can be used in the present invention should be able to hold electrode, an organic luminous layer or a seal. In some embodiments, a glass substrate and a film or sheet made of plastic can be used.

In the case of organic electroluminescence device of bottom emission type, substrate 1 can be translucent.

If substrate 102 is a thin glass substrate of thickness 0.2 mm-1 mm, a thin organic electroluminescence device having large barrier properties can be made.

In addition, when substrate 102 is a flexible plastics film, organic electroluminescence device can be produced on a reel up type film. Therefore, productivity is high, and a cheap device can be provided.

As a plastics film, polyethylene terephthalate, polypropylene, cyclo olefin polymers, polyamide, polyether sulfone, polymethyl methacrylate and polycarbonate can be used.

In addition, first electrode 104 can be formed on one face of substrate 102, and gas barrier properties film can be laminated in the other face of substrate 102. Then barrier properties improve more, and organic electroluminescence device of a long life time can be made.

The following films can be used as a gas barrier properties film: a film deposited ceramic; and a single-layer film such as polyvinylidene chloride, polyvinyl chloride or ethylene-vinyl acetate copolymer saponification material; and a film comprising plural layers of these films.

### First Electrode

Organic electroluminescence device 100 of the present invention has first electrode 104 on substrate 102 as illustrated in FIGS. 1A, 1B and 1C.

First electrode 104 should be thin, uniform conductive film.

Example of first electrode 104 is described below.

Complex oxide (ITO) of indium and tin can be formed by evaporation or sputtering method on translucency substrate 1.

In addition, first electrode 104 can be formed by “coating and thermal decomposition method” as is known by one of ordinary skill in the art.

By way of example only, precursor such as octylic acid indium or acetone indium is applied on substrate. An oxide is formed by thermal decomposition afterwards.

Or metal such as aluminium, gold and silver may be evaporated in semitransparency.

In addition, organic semiconductors such as polyaniline can be used.

In the case of bottom emission type, electrode of transparence or semitransparency is used as first electrode.

When first electrode is anode pouring a hole, the material having a high work function should be selected.

FIG. 1A shows a profile of an organic electroluminescence device. Patterning of first electrode 104 is not done, and partition walls are not installed, either.

In addition, patterning of this first electrode 104 can be performed if necessary. In patterning, a mask of a photosensitive resin is used, and first electrode 104 is etched. By way of example only, in the case of passive matrix driving, stripe-shaped first electrode can be provided with. In FIG. 1B, configuration of first electrode 104 is form of stripe which is parallel in page surface.

Before forming the next layer, surface treatment such as UV processing or plasma treatment can be performed if necessary.

### Partition Wall

A substrate may include partition wall 106 corresponding to a pixel. A partition wall is a wall of insulating properties of some height formed on the substrate on which the first electrode is formed. Partition wall sections each pixel comprising organic electroluminescence device. Partition wall prevents organic luminescence media layer of each pixel from coming out to a neighboring pixel. In addition, a partition wall covers an end of pattern-shaped first electrode. Therefore, a partition wall prevents a short circuit between the second electrode and an end of the first electrode such as ITO. FIG. 1C illustrates a profile of an organic electroluminescence device as well. First electrode 104 is form of a pattern. Partition wall 106 is included to cover an end of first electrode 104.

In addition, FIG. 1B is the figure which a stripe-shaped first electrode and stripe-shaped partition wall is installed in the device. In FIG. 1B, stripe-shaped first electrode is perpendicular to a stripe-shaped partition wall.

A formation method of a partition wall is described below.

Photoresist having photosensitivity and insulating properties is applied on a substrate provided with the first electrode. After having exposed the photoresist through a mask, the photoresist is developed. In this way a partition wall is formed.

By way of example only, photosensitive resin application liquid of negative type is used. This application liquid is exposed through a mask from applied side. In this way, the partition wall that a section is form of reverse taper as shown in FIG. 1B can be formed.

According to the process of the present invention, pattern-shaped organic luminescence media layer is formed by a printing method. Even if height of a partition wall is 10 μm-0.5 μm, mixed color and white emission can be prevented. In addition, organic luminescence ink can be filled in domain sectioned by an partition wall.

And because ink is filled in domain sectioned by the partition wall having a height of 10 μm-0.5 μm by means of a printing method, there is the following merit.

In manufacture of organic luminescence media layer, mixed color and white emission can be sufficiently prevented. When the second electrode and a layer for sealing are laminated, step between a partition wall and pixel parts is small. Therefore, the organic electroluminescence device having a life time that is long can be produced. In addition, yield of manufacture of organic electroluminescence device is high.

In addition, as the substrate that organic luminescence ink is printed, a TFT substrate comprising the following member can be used: a substrate, thin film transistor (TFT) on a substrate corresponding to each pixel, a partition wall covering TFT and pixel electrodes (the first electrodes) of form of pattern corresponding to each pixel.

In this case, it is desirable to form a partition wall of the lattice shape which covers an end of pixel electrodes to prevent a short circuit.

### Organic Luminescence Media Layer

Organic electroluminescence device 100 of the present invention includes organic luminescence layer 114 between the first electrode 104 and the second electrode 122. Organic electroluminescence device 100 of the present invention may include a hole injection layer, a hole transport layer, an electron blocking layer, a buffer layer, an insulator layer, a hole blocking layer, an electron transport layer, an electron injection layer by reason of improvement of luminous efficiency. These are referred to as the luminescence assistance layer in the present specification.

In addition, the organic luminous layer and the luminescence assistance layer which are sandwiched between the first electrode and the second electrode are referred to as organic luminescence media layer 110.

As constitution of organic luminescence media layer 110, the following can be exemplified:

(1) The organic luminescence media layer which combined with a hole transport layer 112 and organic luminous layer 114 as illustrated in FIG. 1A and FIG. 1B;

(2) The organic luminescence media layer which combined with a hole transport layer 112 and, an organic electron transport property luminous layer or an organic hole transport property luminous layer; and

(3) The organic luminescence media layer which combined with a hole transport layer, an organic luminous layer and a electron transport layer illustrated in FIG. 1C.

One layer can have plural functions such as hole transport and luminescence.

### Hole Transport Layer

Organic luminescence media layer 110 which comprises organic electroluminescence device 100 of the present invention may include hole transport layer 112 between anode and organic luminous layer 114.

Material used as hole transport material generally can be used as hole transport material for hole transport layer 112. Hole transport material is exemplified below: copper phthalocyanine and the derivative, and Low molecular weight hole injection transportation material such as the following aromatic amine system: 1,1-bis(4-di-p-tolylamino phenyl)cyclohexane; and N,N′-diphenyl-N,N′-bis(3-methylphenyl)-1,1′-biphenyl-4,4′-diamine; and N,N′-di(one-naphthyl)-N,N′-diphenyl-1,1′-biphenyl-4,4′-diamine.

Above all, by means of macromolecule hole transport material such as mixture with polyaniline, polythiophene, polyvinylcarbazole, poly(3,4-ethylenedioxy thiophene) and polystyrene sulfonate, film production by wet method is possible. Therefore, this macromolecule hole transport material is preferable.

Hole transport ink is made by means of dissolving hole transport material in a solvent. Hole transport ink is applied by coating method to use a slit coating machine, a spin coater, a bar coating machine, a roll coater, a die coating machine and an engraved-roll coater.

Or hole transport ink can be applied on first electrode in the shape of pattern by a printing method and ink jet method after ink is adjusted as hole transport ink.

Hole transport material is adjusted like ink. Hole transport material dissolves in a solvent.

Solvents that can be used include toluene, dimethylbenzene, acetone, methyl ethyl ketone, methyl isobutyl ketone, cyclohexanone, methanol, ethanol, isopropyl alcohol, ethyl acetate, butyl acetate, water or combination of these solvents.

Water or alcohols are especially preferred.

### Organic Luminous Layer

Organic electroluminescence device 100 of the present invention includes an organic luminous layer as the organic luminescence media layer. Or organic electroluminescence device 100 of the present invention includes an organic luminous layer as one part of the organic luminescence media layer.

The organic luminous layer which organic electroluminescence device of the present invention includes is formed by organic luminescence ink of the present invention.

Organic luminescence ink of the present invention includes a solvent and organic luminescent material dissolved in the solvent.

Solvent included by this ink consists of solvent A and solvent B.

As for solvent A, boiling point is under 180 degrees Celsius and more than 70 degrees Celsius at 1 atm.

As for solvent B, boiling point is equal to or less than 270 degrees Celsius and more than 180 degrees Celsius at 1 atm.

Percentage of solvent B in sum of solvent A and solvent B is lower than 30% by weight and more than 5% by weight.

As organic luminescent material used for organic luminescence ink, material used as organic luminescent material generally can be used.

By way of example only, the following material can be used:

The material which fluorescent coloring material such as coumarin system, perylene system, pyran system, anthrone system, polphilene system, quinacridon system, N,N′-dialkyl displacement quinacridon system, naphthalimido system and N,N′-diaryl displacement pyrrolo pyrrole series dissolves in macromolecule such as polystyrene, polymethyl methacrylate and polyvinylcarbazole; and

Macromolecule fluorescent or phosphorus luminous material such as PPV system and PAF system, and polyparaphenylene system.

The following material can be used as solvent B having a boiling point (b.p.) in normal pressure (1.013×10⁵ N/m² (1 atm)) less than 270 degrees Celsius and more than 180 degrees Celsius: 2,3-dimethylanisole, 2,5-dimethylanisole, 2,6-dimethylanisole, trimethyl anisole, tetralin, methyl benzoate, ethyl benzoate, cyclohexylbenzene, n-amyl benzene, tert-amyl benzene, diphenyl ether, dimethyl sulfoxide diphenyl, benzonitrile, aniline, methylaniline, ethylaniline, butyl aniline, ethylene glycol, butylbenzene, benzonitrile and combination thereof.

1 or more kind of material is selected from these appropriately.

Especially the following material has high solubility with organic luminescent material, therefore, it is preferable: 2,3-dimethylanisole, 2,5-dimethylanisole, 2,6-dimethylanisole, trimethyl anisole, tetralin, methyl benzoate, ethyl benzoate, cyclohexylbenzene, n-amyl benzene, tert-amyl benzene, diphenyl ether, dimethyl sulfoxide and combination thereof.

The following material can be used as solvent A having a boiling point (b.p.) in normal pressure (1.013×10⁵N/m² (1 atm)) under 180 degrees Celsius and more than 70 degrees Celsius: toluene, dimethylbenzene, methyl ethyl ketone, methyl isobutyl ketone, ethanol, isopropyl alcohol, ethyl acetate, butyl acetate, anisole, 2-methyl anisole, 3-methyl anisole, 4-methyl anisole, p-cymene, mesitylene, trimethylbenzene, N,N-dimethylformamide, 1,2-dichlorobenzene, 1-carbinyl-2-methylbenzene, 1-carbinyl-3-ethylbenzene, 1-carbinyl-4 ethylbenzene, isopropyl benzene, isopropyl cyclohexane, and combination thereof.

1 or more kind of material is selected from these appropriately.

When a weight ratio of solvent B to sum of solvent A and solvent B is beyond 30 wt %, the following phenomena occurs.

Solvent cannot be removed in a drying step such as heat treatment or reduced pressure processing. Therefore, life time as organic electroluminescence device shortens because solvent remains in an organic luminous layer. In addition, emission intensity falls.

When a weight ratio of solvent B to ink is less than 5wt %, the following phenomena occurs.

Solvent is suddenly removed in heating process or vacuum drying process. Therefore, an organic luminous layer that film thickness is nonuniform is formed. Even more particularly, ink dries during printing. Therefore, the ink is not transferred from the relief printing plate onto a substrate. Therefore, pattern is not sufficiently printed onto a substrate.

It is desirable to adjust ink so that a weight ratio of organic luminescent material to organic luminescence ink is lower than 2.5% by weight and more than 0.8% by weight. It is more desirable to adjust ink so that a weight ratio of organic luminescent material to organic luminescence ink is lower than 2.0% by weight and more than 1.0% by weight. Even more particularly, it is desirable that viscosity of organic luminescence ink is less than 70 mPa.s and more than 10 mPa.s at 25 degrees Celsius. In the case of the above described viscosity, ink is suitable for printing by relief printing method.

It is more preferable for viscosity of organic luminescence ink to be less than 60 mPa.s and more than 15 mPa.s at 25 degrees Celsius. In this viscosity, organic luminescence ink of form of pattern formed on a substrate does not flow out. And levelling of ink happens. Therefore, uniform organic luminous layer can be formed.

In addition, detergent, antioxidant, viscosity modifier and UV absorber may be added in organic luminescence ink if necessary.

### Relief Printing Method

Organic luminescence ink can be used to form an organic luminous layer comprising one part or all part of the organic luminescence media layer which comprises organic electroluminescence device by relief printing method.

Relief printing method is the following printing method.

Relief printing plate is used as printing plate. Ink is held in convex parts of the printing plate. Ink is put from the convex part to a substrate.

The ink for relief printing of the present invention is preferable for relief printing method of relief printing plate made of resin.

In this printing process, metal relief printing plate can be used, too. However, crack may occur in a substrate by pressing force in printing when a substrate is made of weak material such as glass. Therefore, it is desirable to utilize printing plate made of resin.

A manufacturing method of printing plate made of such a resin is explained as follows.

A layer of a photosensitive resin is laminated on a substrate of high dimensional stability such as polyester film. Subsequently a photosensitive resin is exposed through the mask that transmits light only in streak part. Then streak part is stiffened and unexposed non-hardening part is washed away with liquid developer such as a solvent. In this way photosensitive resin relief printing plate can be obtained.

Organic luminescent material of polymer system does not dissolve well in an organic solvent of a water system or alcohol system. In addition, there is harmful effect in the luminescence property when organic luminescent material of polymer system dissolves in an organic solvent of a water system or alcohol system. Therefore it is necessary to dissolve organic luminescent material of polymer system in an organic solvent when the ink which was suitable for coating and printing is made. As this organic solvent, aromatic organic solvent such as toluene or dimethylbenzene is preferred. Thus, among functional ink, organic luminescence ink is ink including aromatic organic solvent. Swelling of relief printing plate by this organic solvent should be prevented. And it should be printed so that streak is precise. Therefore it is desirable to use relief printing plate having resistance against an organic solvent.

It is preferable to use hydrophilic resin as material of such a relief printing plate. Depending on development method, there are the following two kinds of photosensitive resins: the photosensitive resin which can be developed with water; and the photosensitive resin which can be developed with an organic solvent.

A photo-curing type photosensitive resin of water development type is applied to a substrate. And exposure/development is done. Water development type plastic plate made in this way can be used. A water development type photosensitive resin remains hydrophilic after it is hardened. Thus, swelling by oil solubility solvent in functional ink can be prevented.

As such a water development type photo-curing type photosensitive resin, mixture of a hydrophilic polymer and polymer having unsaturated bonding can be exemplified. As hydrophilic polymer, polyamide, polyvinyl alcohol, and a cellulose derivative can be exemplified. In addition, as unsaturated bonding, vinyl bonding can be exemplified. As polymer having vinyl bonding, methacrylate system polymer can be exemplified. Photoresponsive initiator may be mixed in this water development type photo-curing type photosensitive resin. Aromatic carbonyl compound can be used as photoresponsive initiator.

In addition, when a substrate is glass, it is preferable to use a soft plastic plate. On the other hand, when a substrate is various plastic sheeting, a plastic film, printing plate except plastic plate can be used. This is because plastic sheeting, a plastics film are hard to be broken.

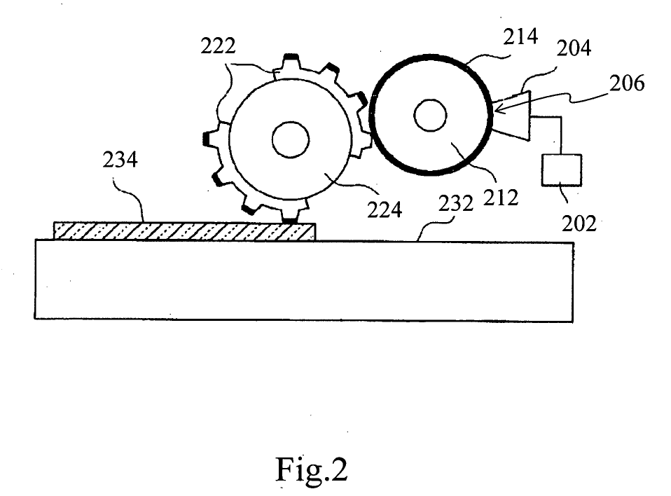

A schematic illustration of relief printing device was shown in FIG. 2. This relief printing device prints organic luminescence ink on a substrate. This relief printing device has ink tank 202, ink chamber 204, anilox roll 212 and plate cylinder 224 that printing material 222 is equipped with. Printing material 222 includes plastic plate. Organic luminescence ink is taken to ink tank 202. Organic luminescence ink is sent into ink chamber 204 from ink tank 202. Anilox roll 212 makes contact with ink feed section 206 of ink chamber 204, and it is rotatably supported.

With rotation of anilox roll 212, ink layer 214 supplied in anilox roll surface is formed with uniform thickness. The ink of this ink layer is transferred to a convex part of printing material 222 rotationally driven in proximity to anilox roll. Substrate 234 is transported to printing position of flat-bed printing machine 232 by the transporting means that is not illustrated. And ink on a convex part of printing material 222 is printed onto substrate 234.

Ink is dried if necessary. An organic luminous layer is formed on a substrate in this way.

The processes can be performed multiple times. Inks including the organic luminescent materials of a different luminescent color can be used. In this way organic electroluminescence device of color display can be produced.

Film thickness of an organic luminous layer is equal to or less than 1 μm. As for the film thickness of an organic luminous layer, it is preferable to be 0.05 μm -0.15 μm. As for the film thickness of an organic luminous layer, it is more preferable to be 0.05 μm -0.08 μm.

Organic luminescence ink of the present invention is used, by means of relief printing method, the uniform membrane of the film thickness difference in a pixel is lower than ±0.01 μm can be formed.

Even more particularly, by means of optimizing printing speed and an amount of ink feeding, film thickness difference in a substrate becomes lower than ±0.005 μm.

In addition, organic luminescence ink of the present invention can be applied when an organic luminous layer is formed by an intaglio printing represented by a gravure printing method and an ink jet printing method as well as relief printing method.

Drying time of organic luminescence ink placed on a substrate can be shortened by drying under heating and/or reduced pressure. Composition of solvent of organic luminescence ink of the present invention is optimized. Therefore, by means of using organic luminescence ink of the present invention, uniform organic luminous layer can be formed. A method to remove solvent under heating and reduced pressure environment is more desirable.

### Electron Transport Layer

Organic luminescence media layer 110 which comprises organic electroluminescence device 100 of the present invention may include electron transport layer 116 between cathode and organic luminous layer 114.

As electron transport material used for electron transport layer 116, the following material is exemplified:

2-(4-Biphenyl-il)-5-(4-t-butylphenyl)-1,3,4-oxadiazole, 2,5-Bis(1-naphthyl) -1,3,4-oxadiazole, Oxadiazoles, Bis(10-hydroxybenzo[H]quinolinolate)beryllium complex, and triazole compound.

Vacuum deposition can be applied to the formation of electron transport layer. In addition, depending on the material, the luminescence assistance layer which is necessary can be formed by wet processing or dry process. Organic luminescence media layer includes the organic luminous layer and luminescence assistance layer.

### Second Electrode

Next, second electrode 122 is formed on the organic luminous media layer 110 as illustrated in FIG. 1A, FIG. 1B and FIG. 1C.

When the second electrode is cathode provided over an organic luminous layer and an electron transport layer, the following material is used: the material that electron injection efficiency to functional layer such as electron transport layer is high and work function is low.

In some embodiments, metal such as Mg, Al and Yb can be used. In addition, the following second electrode may be used: thin layer such as Li or LiF of film thickness about 1 nm is provided on the surface of organic luminescence media layer; and the metal membrane with high chemical stability is laminated on this thin layer. Al and Cu can be exemplified for such a metal having high stability.

In addition, the following material can be used as material of second electrode to balance stability with electron injection efficiency: alloy with the metal having low work function and metals which are stable. For example, MgAg, AlLi, and CuLi can be used as such an alloy.

This second electrode can be formed by methods such as resistance heating evaporation method, eletron beam method and sputtering method. It is desirable for thickness of the second electrode to be about 10-1000 nm. In the case of organic electroluminescence device of so-called top emission type, material with translucency can be used for the second electrode.

By means of forming extremely thin membrane, the second electrode that transmits light is formed.

Second electrode 122 can be formed selectively in area of a pixel of organic electroluminescence device. By way of example only, second electrode 122 can be formed in predetermined configuration by evaporating through a mask.

In FIG. 1B, second electrode 122 can be formed to the direction which is perpendicular to first electrode 104. Second electrode 122 can be formed between stripe-shaped partition wall 106. Second electrode 122 can be formed of stripe in correspondence with a pixel.

Second electrode 122 can be formed by evaporating from the upper part of the stripe-shaped partition wall that has a reverse tapered profile configuration. Second electrode can be formed in divided configuration in correspondence with configuration of a partition wall by such an evaporation. Therefore, configuration of second electrode can be configuration of the stripe which is perpendicular to the first electrode.

In addition, for example, the second electrode can be formed in the shape of stripe by a well-known photolithography method.

### Process to Seal

Because electric current flows to an organic luminous layer between electrodes, organic electroluminescence device emits light. However, an organic luminous layer deteriorates by means of atmospheric moisture and oxygen. Thus a seal is usually installed on an organic luminous layer to isolate an organic luminous layer from the outside.

A seal can be made as follows. Substrate 136 for sealing is adhesively bonded by adhesive 134. Thin film 132 to seal on the second electrode side may be provided more as illustrated in FIG. 1C. Example of thin film 132 for sealing is described below.

Inorganic thin film can be used. In some embodiments, by means of CVD method, silicon-nitride film of thickness 150 nm is layered on the second electrode directly.

About sealing by thin film, it is preferable to complete sealing only with thin film. When organic electroluminescence device is sealed only by thin film, manufacturing process of organic electroluminescence device can be simplified. In addition, organic electroluminescence device can be formed thinly.

But performance of the present thin film for sealing is undesirable. Therefore, when substrate for sealing is used together with the present thin film for sealing, emission lifetime is longer.

The following adhesive can be used as adhesive 134: Photo-curing type adhesive property resin; heat curing type adhesive property resin and 2 fluid hardening type adhesive property resin comprising epoxy system resin, acrylic resin, silicone oil and the like; acrylic resin such as ethylene ethylacrylate (EEA) polymer; vinyl resin such as ethylene vinyl acetate (EVA); thermoplastic resin such as polyamide and synthetic rubber; thermoplastic adherent resin such as acid denatured substances of polyethylene or polypropylene.

A method to form an adhesive layer on second electrode 122 or thin film 132 for sealing is described below.

Solvent solution method, “pushing out” laminate method, fusion/hot melt method, calendar method, nozzle application method, screen printing, vacuum laminate method and heated roll laminate method can be used.

When resin of ultraviolet cure type is used and thin film for sealing is bonded to the second electrode, an organic luminous layer is not heated. Therefore, degradation of an organic luminous layer by heat does not occur. In addition, organic electroluminescence device is a layer stack of material of various coefficient of thermal expansion. Modification of organic electroluminescence device and break-down of some layer can be prevented.

On the other hand, luminescent material deteriorates due to ultraviolet radiation. Therefore, adhesive is placed at area except domain emitting light as a pixel. Ultraviolet radiation is irradiated in area except a light emitting area. By way of example only, in the case of irradiation, masking means such as masks can be used.

Material having hygroscopicity and character absorbing oxygen can be incorporated into adhesive if necessary.

Depending on size and configuration of an organic electroluminescence display unit to seal, thickness of adhesive is decided. In some embodiments, it is desirable for thickness of adhesive to be about 5-500 μm.

Adhesive can be placed at a whole area of substrate for sealing. In addition, adhesive can be formed in the shape of frame to seal surroundings.

Substrate 136 for sealing should have low moisture and oxygen transmissivity. The following material can be used as material of substrate 136 for sealing: ceramics such as alumina, silicon nitride and boron nitride; glass such as a no alkali glass and alkali glass; quartz; metallic foil comprising aluminium, stainless and the like; and a humidity resistance film.

Examples of a humidity resistance film include: a film which is formed of SiOx by CVD method on both sides of a plastic substrate; a laminated film of a film with low moisture and oxygen transmissivity; hydrophilic film; a film which water absorption agent was applied on the film with low moisture and oxygen transmissivity.

It is preferable for moisture or vapor transmission of a humidity resistance film to be less than 10⁻⁶ g/m²/day.

Examples of configuration of substrate for sealing include: configuration of a flat board, configuration of a film, and cap configuration as referred to as a can for sealing.

After having applied adhesive on the second electrode side, substrate for sealing can be bonded to the second substrate. After having applied adhesive on the substrate side for sealing, substrate for sealing can be bonded to the second electrode.

By way of example only, adhesive is applied on a whole area of the substrate side for sealing. Under vacuum or dry inert gas, substrate for sealing can be affixed to the second electrode of organic electroluminescence device afterwards.

When organic electroluminescence device is sealed with substrate for sealing and adhesive of thermoplastic resin is used in some embodiments, only contact bonding by a heating roller should be performed.

When heat curing type adhesion resin is used as adhesive, even more particularly, in some embodiments heating/hardening of adhesive should be done in cure temperature after contact bonding by a heating roller.

When photo-curing type adhesion resin is used as adhesive, even more particularly, adhesive can be stiffened by an irradiation by light after contact bonding by roll.

In this way, sealed organic electroluminescence device can be obtained.

For example, as for the produced organic electroluminescence device, organic luminous layer 114 emits light by application of voltage of about 10V. The transparent electrode which is the first electrode can be used as anode. The counter electrode which is the second electrode can be used as cathode as illustrated in FIG. 1B.

Character and image can be displayed by the whole of these pixels by control of applied voltage every pixel sectioned by a partition wall.

### EXAMPLE 1

An example is explained below according to FIG. 1B.

Organic luminescence ink of the present invention was used, and passive driving type organic electroluminescence-device of bottom emission type was made.

An estimate method of organic electroluminescence device provided in an example/comparative example is explained below.

Variation of film thickness and luminance in one pixel is measured. Five pixels in one device chosen at a venture are measured. Film thickness unevenness and luminance unevenness of an organic luminous layer were evaluated based on average value of the five data. Film thickness unevenness was measured by “P-15, a product of KLA-Tencor”.

When film thickness unevenness is equal to or less than ±3%, it was estimated as, o. When film thickness unevenness is bigger than 3%, it was estimated as, x. When luminance unevenness is equal to or less than ±10%, it was estimated as, o. When luminance unevenness is bigger than 10%, it was estimated as, x.

Each estimate is shown in table 1.

A transparent glass substrate of 100 mm every side was prepared for substrate 102. Substrate 102 was provided with the first electrode (ITO) which was transparent and of form of line of 800 μm pitch (L/S=700/100).

A photo-curing type photosensitive resin was applied on a whole area of the substrate which the first electrode is provided. Partition wall 106 was provided by exposure/development. Partition wall 106 divides cathode. Configuration of partition wall 106 is form of stripe of 800 μm pitch. Height of partition wall is 2 μm. Partition wall 106 is perpendicular to the first electrode. Profile of partition wall 106 is reverse taper configuration.

A manufacturing method of hole transport layer 112 is explained below. The water dispersion solution that density of poly (3,4-ethylenedioxy thiophene) presented in (chemical formula 1) and polystyrene sulfonate (following PEDOT/PSS) was 1 wt % was prepared. Detergent of ether pro-higher alcohol (EMULGEN 105 (a product made in Kao Corporation, non-ion)) were added in this water dispersion solution. An amount of EMULG-EN 105 is 0.5% against PEDOT/PSS.

Solution made in this way was adjusted like ink.

Slit coat method was used, and this ink of thickness 80 nm was applied.

In this way hole transport layer 112 was formed.

Substrate 234 was prepared for in this way.

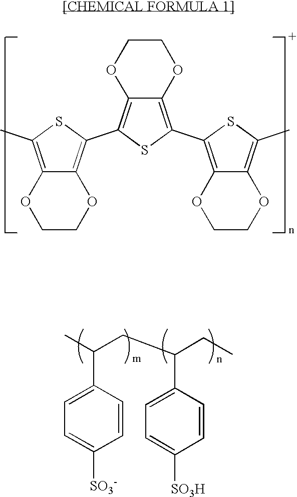

Then subsequently organic luminescence ink was adjusted.

Organic luminescent material MEH-PPV presented in (chemical formula 2) was dissolved in combined solvent of mesitylene (boiling point 165 degrees Celsius) and tetralin (boiling point 208 degrees Celsius).

Organic luminescence ink was made in this way.

About composition of this ink, MEH-PPV is 1 wt %, and solvent is 99wt %.

About composition of solvent, a weight ratio of mesitylene is 80% and a weight ratio of tetralin is 20%.

A printing material used for relief printing method was prepared.

On polyester film substrate, the water development type polyamide system photosensitive resin layer was laminated. Ultraviolet radiation was irradiated through a mask of predetermined pattern. It was developed with water. Relief printing plate comprising substrate and water development type photosensitive resins was produced in this way. The pattern was form of stripe of L/S=700/100 corresponding to partition wall 106.

And relief printing device in FIG. 2 having this relief printing plate was used, and the organic luminescence ink was printed in the shape of pattern on hole transport layer 112 on substrate 234. The organic luminescence ink was printed onto domain sectioned by partition wall 106. The thickness of provided organic luminous layer 114 was 80 nm. The thickness of this organic luminous layer 11 was uniform.

Subsequently second electrode 122 (cathode) are explained below.

MgAg was laminated by the two-source evaporation method. The thickness of MgAg was 200 nm. In addition, partition wall 106 was form of reverse taper. Therefore, the cathode was formed in the shape of pattern.

Photo-curing type adhesive was applied to the second electrode side of organic electroluminescence device, and glass cap was bonded last.

Organic electroluminescence device was sealed in this way.

In this way organic electroluminescence device of passive driving type was made.

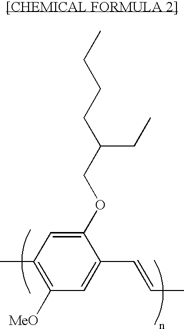

In provided passive driving type organic electroluminescence device, leakage current did not occur. In addition, only all selected pixels turned on. The luminescence was 100 cd/m² at 5V. The luminescence was uniform.

In addition, the initial luminance was 400 cd/m². The half life was 200 hours.

About uniformity in a pixel, estimate result of film thickness unevenness and luminance unevenness is shown for the following table 1.

### COMPARATIVE EXAMPLE 1

As for the substrate comprising the first electrode and partition walls and a hole transport layer, a substrate same as example 1 was prepared.

About composition of organic luminescence ink forming an organic luminous layer, MEH-PPV is 1 wt %, and solvent is 99wt %. Toluene (boiling point 110 degrees Celsius) of 100% was used as solvent. Other is similar to example 1.

The formation of pattern-shaped organic luminous layer was performed by relief printing method on substrate 234 same as example 1.

However, ink dried on relief printing plate, and it hardened. Organic luminescence ink on relief printing plate was not able to be printed onto a substrate sufficiently.

In addition, surface roughness Rz of the organic luminous layer which was able to be printed was measured. Surface roughness Rz was 21 nm.

### COMPARATIVE EXAMPLE 2

As for the substrate comprising the first electrode and partition walls and a hole transport layer, a substrate same as example 1 was prepared.

About composition of organic luminescence ink forming an organic luminous layer, MEH-PPV is 1 wt %, and solvent is 99wt %.

About solvent, a weight ratio of dimethylbenzene (boiling point 139 degrees Celsius) was 85% and a weight ratio of anisole (boiling point 154 degrees Celsius) was 15%. Other is similar to example 1.

The formation of pattern-shaped organic luminous layer was performed by relief printing method on substrate 234 same as example 1. Subsequently second electrode is formed same as example 1, and it was sealed.

However, due to high-speed evaporation of solvent, an organic luminous layer of uniform thickness was not able to be formed. The provided passive driving type organic electroluminescence device emitted light unevenly.

About uniformity in a pixel, estimate result of film thickness unevenness and luminance unevenness is shown in the following table 1.

In addition, the film thickness unevenness was ±7%.

Greatest surface roughness Rmax was 20 nm.

The luminance unevenness was ±40%.

### COMPARATIVE EXAMPLE 3

As for the substrate comprising the first electrode and partition walls and a hole transport layer, a substrate same as example 1 was prepared.

About composition of the organic luminescence ink forming an organic luminous layer, MEH-PPV was 1 wt %, and solvent was 99wt %.

For solvent, a weight ratio of mesitylene (boiling point 165 degrees Celsius) was 20% and a weight ratio of tetralin (boiling point 208 degrees Celsius) was 80%. Other is similar to example 1.

The formation of pattern-shaped organic luminous layer was performed by relief printing method on substrate 234 same as example 1. Subsequently second electrode is formed same as example 1, and it was sealed.

About provided passive driving type organic electroluminescence device, leakage current did not flow.

In addition, only all selected pixels were able to be turned on.

Luminance was 10 cd/m² at 5V and it was lower than luminance of organic electroluminescence device provided in example 1.

In addition, initial luminance was 400 cd/m², and half life was ten hours and it was shorter.

About uniformity in a pixel, estimate result of film thickness unevenness and luminance unevenness is shown in the following table 1.

### COMPARATIVE EXAMPLE 4

As for the substrate comprising the first electrode and partition walls and a hole transport layer, a substrate same as example 1 was prepared.

About composition of the organic luminescence ink forming an organic luminous layer, MEH-PPV was 1 wt %, and solvent was 99wt %.

For solvent, a weight ratio of mesitylene (boiling point 165 degrees Celsius) was 98% and a weight ratio of tetralin (boiling point 208 degrees Celsius) was 2%. Other is similar to example 1.

The formation of pattern-shaped organic luminous layer was performed by relief printing method on substrate 234 same as example 1.

Ink dried on relief printing plate, and it hardened. There was the pattern which was not transferred.

In addition, about transferred organic luminous layer, unevenness was observed by visual inspection.

### COMPARATIVE EXAMPLE 5

As for the substrate comprising the first electrode and partition walls and a hole transport layer, a substrate same as example 1 was prepared.

As for the composition of the organic luminescence ink forming an organic luminous layer, MEH-PPV was 1 wt %, and solvent was 99wt %.

For solvent, a weight ratio of mesitylene (boiling point 165 degrees Celsius) was 50% and a weight of tetralin (boiling point 208 degrees Celsius) was 50%. Other is similar to example 1.

The formation of pattern-shaped organic luminous layer was performed by relief printing method on substrate 234 same as example 1. Subsequently the second electrode was formed same as example 1, and it was sealed.

About provided passive driving type organic electroluminescence device, leakage current did not flow.

Only all selected pixels were able to be turned on.

Luminance was 50 cd/m² at 5V and it was lower than luminance of organic electroluminescence device provided in example 1.

In addition, initial luminance was 400 cd/m², and half life was 20 hours and it was shorter.

About uniformity in a pixel, estimate result of film thickness unevenness and luminance unevenness is shown in the following table 1.

TABLE 1

| | | SOLVENT B | | | |
|---|---|---|---|---|---|
| | SOLVENT A | b.p. (more than | | | |
| | b.p. (more than | 180° C. and | | Film | |
| | 70° C. and under | less than | | thickness | Luminance |
| | 180° C.) | 270° C.) | A/B | unevenness | unevenness |
| EXAMPLE 1 | Mesitylene | Tetralin | 80/20 | ◯ | ◯ |
| | (b.p. 165° C.) | (b.p. 208° C.) | | | |
| COMPARATIVE | Toluene | — | 100/0 | X | — |
| EXAMPLE 1 | (b.p. 110° C.) | | | | |
| COMPARATIVE | A₁ | — | A₁/ | X | X |
| EXAMPLE 2 | Dimethylbenzene | | A₂ = 85/15 | | |
| | (b.p. 130° C.) | | | | |
| | A₂ Anisole | | | | |
| | (b.p. 154° C.) | | | | |
| COMPARATIVE | Mesitylene | Tetralin | 20/80 | ◯ | ◯ |
| EXAMPLE 3 | | | | | |
| COMPARATIVE | Mesitylene | Tetralin | 98/2 | X | X |
| EXAMPLE 4 | | | | | |
| COMPARATIVE | Mesitylene | Tetralin | 50/50 | ◯ | ◯ |
| EXAMPLE 5 | | | | | |

What is claimed is:

1. An organic luminescence ink comprising a solvent and an organic luminescent material dissolved in the solvent,
said solvent includes solvent A having a boiling point more than 70 degrees Celsius and under 180 degrees Celsius and solvent B having a boiling point more than 180 degrees Celsius and less than or equal to 270 degrees Celsius, wherein an amount of solvent B in sum of an amount of solvent A and solvent B is more than 5% by weight and less than or equal to 30% by weight.

2. The organic luminescence ink according to claim 1, wherein said solvent B is selected from a group consisting of 2,3-dimethylanisole, 2,5-dimethylanisole, 2,6-dimethylanisole, trimethyl anisole, tetralin, methyl benzoate, ethyl benzoate, cyclohexylbenzene, n-amyl benzene, tert-amyl benzene, diphenyl ether, dimethyl sulfoxide, and combinations thereof.

3. A manufacturing method of an organic electroluminescence device including a substrate, a first electrode, an organic luminous layer, and a second electrode,
said method comprising
preparing the substrate having the first electrode, and
forming organic luminescence layer on the substrate by relief printing method using the organic luminescence ink according to claim 1.
